(19) United States
(12) Patent Application Publication
(10) Pub. No.: US 2023/0273340 A1
(43) Pub. Date: Aug. 31, 2023

(54) Method for dynamically changing a WRF parameterization scheme combination based on a surface pressure distribution situation

(71) Applicant: CHINA INSTITUE OF WATER RESOURCES AND HYDROPOWER RESEARCH, Beijing (CN)

(72) Inventors: Mingxiang Yang, Beijing (CN); Hao Wang, Beijing (CN); Yunzhong Jiang, Beijing (CN); Yong Zhao, Beijing (CN); Ningpeng Dong, Beijing (CN)

(21) Appl. No.: 18/008,156

(22) PCT Filed: Mar. 31, 2021
(86) PCT No.: PCT/CN2021/084263

§ 371 Date: Dec. 2, 2022

(30) Foreign Application Priority Data
Jun. 8, 2020 (CN) 202010513026.1

(51) Int. Cl. G01W 1/10

(52) U.S. Cl. CPC G01W 1/10

(57) ABSTRACT

A method for dynamically changing a WRF parameterization scheme combination based on a surface pressure distribution situation includes steps of (S1) constructing a database having a corresponding relation between a historical surface pressure distribution situation and an optimal parameterization scheme combination; and (S2) obtaining an optimal parameterization scheme combination corresponding to the historical surface pressure distribution situation by querying a historical surface pressure distribution situation closest to an actual precipitation forecast surface pressure distribution situation in the database, and running WRF by the optimal parameterization scheme combination corresponding to the historical surface pressure distribution situation, so as to carry out an actual precipitation forecast. The present invention has advantages as follows. The method uses the principle of high correlation between the surface pressure distribution situation and the weather situation to build a database of the surface pressure distribution situation and the optimal parameterization scheme combination, and takes the surface pressure distribution situation at the beginning of forecast as the basis for selecting the optimal parameterization scheme combination, which is able to indirectly reflect the applicability of different parameterization scheme combinations to different weather situations, thus the method provided by the present invention has higher prediction accuracy than the traditional method.

### BACKGROUND OF THE PRESENT INVENTION

### Field of Invention

The present invention relates to the field of meteorological and hydrological forecasting technology, and more particularly to a method for dynamically changing a WRF (weather research and forecasting model) parameterization scheme combination based on a surface pressure distribution situation.

### Description of Related Arts

Numerical weather prediction is a method which includes on the basis of actual atmospheric conditions, at certain initial values and boundary values, solving the equations of fluid mechanics and thermodynamics which describe weather evolution by performing numerical calculation with the large-scale computer, so as to predict atmospheric motion and weather phenomena in a certain period of time in the future.

WRF (weather research and forecasting model) is a unified mesoscale weather forecasting model developed by NCEP (National Centers for Environmental Prediction), NCAR (National Center for Atmospheric Research), and several universities, research institutes, and business groups. It is one of the most advanced numerical weather forecasting models in the world and has been widely used.

Parameterization schemes such as microphysics, cumulus convection, radiation, planetary boundary layer and land surface processes are important components of the WRF and important means to explain various weather phenomena at sub-grid scale. Among them, the microphysical parameterization scheme and the cumulus convection parameterization scheme have great influence on the performance of precipitation simulation and forecast. Since the WRF is jointly maintained by many researchers around the world, there are multiple options for each parameterization scheme. Now, the microphysical parameterization scheme and the cumulus convection parameterization scheme that have great influence on precipitation simulation and forecast are introduced as follows.

At present, the widely used microphysical parameterization schemes are (1) Kessler scheme which is a simple warm cloud precipitation scheme, in which the microphysical processes are mainly rainwater generation, fall and evaporation processes, and condensation generation, collision growth and automatic transformation processes of cloud water; in the microphysical processes, water vapor, cloud water and rainwater are explicitly forecast, there is no ice-phase process, Kessler scheme is widely used in the study of idealized cloud models; (2) Lin scheme which is a complex and relatively mature microphysical scheme in the WRF, in which the hydrometeors in this scheme include water vapor, cloud water, cloud ice, rain, snow and graupel, Lin scheme is a scheme suitable for theoretical research applications and real-time data high-resolution simulation; (3) WSM6 scheme which includes some graupel-related processes suitable for the study of high-resolution simulation schemes, compared with WSM-5 scheme considering five kinds of hydrometeors such as water vapor, cloud water, rain, cloud ice and snow; (4) Thompson scheme which is a new microphysical parameterization scheme including ice, snow and graupel and suitable for the WRF or other mesoscale models; (5) Morrison scheme which is a completely two-parameter scheme for forecasting the mixing ratio and the number concentration of five kinds of hydrometeors such as Cloud droplets, cloud ice, snow, rain and graupel. The scheme explicitly solves the saturation and condensation/desublimation in the cloud.

At present, the widely used cumulus convection parameterization schemes include: (1) Kain-Fritsch scheme which is a mass flux parameterization scheme, uses Lagrangian air parcel theory to judge whether there is instability and whether instability will lead to cloud growth, and uses the deep convection and shallow convection sub-grid scheme with downdraft and convective available potential energy (CAPE) movable time scale; (2) Betts-Miller-JanJic scheme which is modification and improvement of Betts-Miller scheme, in which cloud formation efficiency parameters are introduced, the scheme is a convection adjustment scheme, and the shallow convection adjustment is an important part of the scheme; (3) Grell3 scheme which has higher resolution, considers the sinking effect in the adjacent column area, and the sinking effect is able to spread to the surrounding points compared to other cloud parameterization schemes.

Because different parameterization schemes are often developed by different teams, the physical mechanisms considered are different, and the details of cloud rain occurrence, development and extinction are different. Therefore, atmospheric states simulated by different parameterization schemes are not completely consistent with each other. However, the atmospheric phenomena vary greatly, and the weather phenomena in the same area and at different times vary greatly. The same precipitation level may be caused by different weather types. It is able to be seen that on the one hand, there are a large number of parameterization scheme combinations, on the other hand, the complex and changeable weather phenomena make the setting of parameterization scheme combinations a very complex task in the WRF.

At present, the methods of setting the WRF microphysical and cumulus convection parameterization schemes include:
(1) Default method, which uses the parameterization scheme combination defaulted in the WRF as the parameterization scheme combination for future forecast;
(2) Historical holistic optimal method, which selects a set of parameterization scheme combination with the best forecast effect for a region in the past period of time (such as 1 year or many years) as the parameterization scheme combination used in the future forecast. This method generally requires a long time simulation to evaluate the performance effect of each parameterization scheme in a certain area;
(3) Historical seasonal optimal method, which is able to further evaluate the overall performance of different parameterization schemes in different seasons on the basis of the historical holistic optimal method, and select the relatively optimal parameterization scheme combination for different seasons, that is, configuring a set of relatively optimal parameterization scheme combination for each season.

However, all the methods (1) to (3) ignore the different forecasting performance of different parameterization schemes for different weather conditions to different degrees, which is inconsistent with the actual situation and leads to poor forecasting effect.

### SUMMARY OF THE PRESENT INVENTION

An object of the present invention is to provide a method for dynamically changing a WRF (weather research and forecasting model) parameterization scheme combination based on a surface pressure distribution situation, so as to solve the above problems in prior arts

To achieve the above object, the present invention provides technical solutions as follows.

A method for dynamically changing a WRF parameterization scheme combination based on a surface pressure distribution situation comprises steps of:
(S1) constructing a database having a corresponding relation between a historical surface pressure distribution situation and an optimal parameterization scheme combination; and
(S2) obtaining an optimal parameterization scheme combination corresponding to the historical surface pressure distribution situation by querying a historical surface pressure distribution situation closest to an actual precipitation forecast surface pressure distribution situation in the database, and running WRF by the optimal parameterization scheme combination corresponding to the historical surface pressure distribution situation, so as to carry out an actual precipitation forecast, wherein:
before the step of (S1), the method further comprises a step of setting a forecast period of numerical precipitation forecast according to forecast demands;
the step of (S1) specifically comprises:
   (S11) determining a start time and an end time of the forecast period;
   (S12) determining a parameterization scheme combination sample set;
   (S13) determining a WRF operation scheme;
   (S14) carrying out the WRF by each parameterization scheme combination;
   (S15) obtaining surface pressure distribution data at a beginning of each WRF operation and a parameterization scheme combination with a minimum forecast error of the each WRF operation; and
   (S16) obtaining surface pressure distribution data at the beginning of all WRF operations and all parameterization scheme combinations with the minimum forecast error of the all WRF operations by repeating the steps of (S14) and (S15) and storing, so as to obtain the database having the corresponding relation between the historical surface pressure distribution situation and the optimal parameterization scheme combination.

Preferably, the parameterization scheme combination sample set comprises microphysical parameterization schemes and cumulus convection parameterization schemes.

Preferably, the step of (S13) specifically comprises on a basis of determining the start time, the end time and the parameterization scheme combination sample set, determining the WRF parameterization scheme in combination with the forecast period.

Preferably, the step of (S15) specifically comprises obtaining the surface pressure distribution data at the beginning of the each WRF operation, calculating an precipitation forecast error of the each parameterization scheme combination of the each WRF operation, selecting the parameterization scheme combination with the minimum forecast error of the each WRF operation as an optimal parameterization scheme combination of the each WRF operation, and building a corresponding relation between the optimal parameterization scheme combination and the surface pressure distribution data at the beginning of the each WRF operation.

Preferably, the precipitation forecast error of the each parameterization scheme combination is calculated by a formula of

$$Δ P = \vert {\sum }_{d = 1}^{λ} {Pre}_{d} - {\sum }_{d = 1}^{λ} {Obs}_{d} \vert ,$$

wherein ΔP is the precipitation forecast error of the each parameterization scheme combination, λ is the forecast period, Pre_{d} is a precipitation forecast of the d^{th} day, Obs_{d} is an observed precipitation value of the d^{th} day.

Preferably, the step of (S3) specifically comprises:
(S21) obtaining a surface pressure distribution situation at a beginning of the actual precipitation forecast;
(S22) querying a historical surface pressure distribution situation which is most closest to the surface pressure distribution situation at the beginning of the actual precipitation forecast in the database, wherein an optimal parameterization scheme combination corresponding to the historical surface pressure distribution situation is an optimal parameterization scheme combination of the actual precipitation forecast; and
(S23) carrying out the actual precipitation forecast by carrying out the WRF operation with the optimal parameterization scheme combination of the actual precipitation forecast.

Preferably, the database comprises multiple historical surface pressure distribution situations; each of the multiple historical surface pressure distribution situations is obtained by analyzing FNL (final operational global analysis) data in the WFP mode, and storing surface pressure distribution data of a research area in a corresponding historical surface pressure distribution matrix file in a form of rows and columns, so as to form the historical surface pressure distribution situation; the surface pressure distribution situation at the beginning of the actual precipitation forecast is obtained by analyzing the FNL data, and storing the surface pressure distribution data of the research area in an actual precipitation forecast surface pressure distribution matrix file in the form of rows and columns, so as to form the surface pressure distribution situation at the beginning of the actual precipitation forecast.

Preferably, the step of (S22) specifically comprises calculating a degree of deviation between the surface pressure distribution situation at the beginning of the actual precipitation forecast and each historical surface pressure distribution situation in the database, finding a historical surface pressure distribution situation with a smallest degree of deviation by traversing all historical surface pressure distribution situations in the database, wherein the historical surface pressure distribution situation with the smallest degree of deviation is the historical surface pressure distribution situation which is most closest to the surface pressure distribution situation at the beginning of the actual precipitation forecast, the optimal parameterization scheme combination corresponding to the historical surface pressure distribution situation with the smallest degree of deviation is the optimal parameterization scheme combination of the actual precipitation forecast, the degree of deviation is calculated by a formula of

$${ε}^{h} = {\sum }_{i = 1}^{m} {\sum }_{j = 1}^{n} \vert {P}_{i , j} - {P}_{i , j}^{h} \vert ,$$

here, ε^{h} is a degree of deviation between the surface pressure distribution situation at the beginning of the actual precipitation forecast and a h^{th} historical surface pressure distribution situation, i is row number, j is column number, m is a largest row number, n is a largest column number, P_{i,j} is a pressure value of i^{th} row, j^{th} column in the actual precipitation forecast surface pressure distribution matrix file, P_{i,j}^{h} is a pressure value of the i^{th} row, j^{th} column in the historical surface pressure distribution matrix file.

The present invention has beneficial effects as follows. (1) The traditional methods ignore the difference of the effect of different parameterization scheme combinations in simulating different weather phenomena. The method uses the principle of high correlation between the surface pressure distribution situation and the weather situation to build a database of the surface pressure distribution situation and the optimal parameterization scheme combination, and takes the surface pressure distribution situation at the beginning of forecast as the basis for selecting the optimal parameterization scheme combination, which is more scientific than the traditional parameterization scheme combination. (2) The microphysical parameterization scheme and the cumulus convection parameterization scheme are two key parameterization schemes affecting the accuracy of precipitation forecast. The present invention selects a parameterization scheme combination according to the surface pressure distribution situation at the beginning of forecast, which is able to indirectly reflect the applicability of different parameterization scheme combinations to different weather situations, thus the method provided by the present invention has higher prediction accuracy than the traditional methods.

### BRIEF DESCRIPTION OF THE DRAWINGS

FIG. 1 is a flow chart of a method for dynamically changing a WRF (weather research and forecasting model) parameterization scheme combination on the basis of a surface pressure distribution situation according to a preferred embodiment of the present invention.

### DETAILED DESCRIPTION OF THE PREFERRED EMBODIMENT

In order to make the objectives, technical solutions and advantages of the present invention clearer, the present invention will be further described in detail as below with reference to accompanying drawings. It should be understood that the specific embodiments described herein are merely illustrative of the present invention and are not intended to limit the present invention.

### First Embodiment

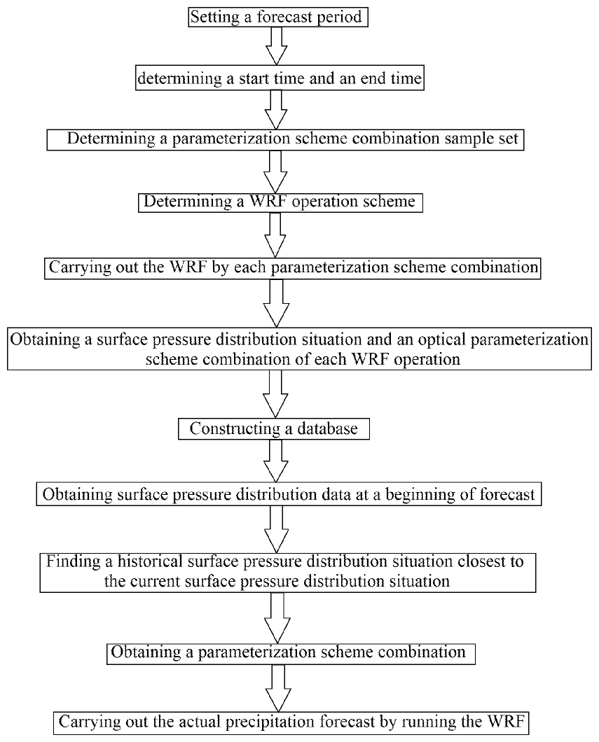

Referring to FIG. 1, a method for dynamically changing a WRF (weather research and forecasting model) parameterization scheme combination based on a surface pressure distribution situation according to a first preferred embodiment of the present invention is illustrated. The method comprises steps of:
(S1) constructing a database having a corresponding relation between a historical surface pressure distribution situation and an optimal parameterization scheme combination; and
(S2) obtaining an optimal parameterization scheme combination corresponding to the historical surface pressure distribution situation by querying a historical surface pressure distribution situation closest to an actual precipitation forecast surface pressure distribution situation in the database, and running a WRF by using the optimal parameterization scheme combination closest to the actual precipitation forecast surface pressure distribution situation, so as to carry out an actual precipitation forecast.

Preferably, before the step of (S1), the method further comprises a step of setting a forecast period of numerical precipitation forecast according to forecast demands.

According to the preferred embodiment, under different weather conditions, different parameterization scheme combinations have different effects, that is, different parameterization schemes have different forecasting abilities for precipitation caused by different weather conditions. The surface pressure distribution situation is an important index to reflect the weather situation. Based on the above characteristic, the corresponding relation between the surface pressure distribution situation and the parameterization scheme combination with the highest forecast accuracy corresponding to the surface pressure distribution situation is able to be established. On the basis of the corresponding relation, the WRF parameterization scheme combination is able to be dynamically set according to the surface pressure distribution situation while forecasting, so as to dynamically change the WRF parameterization scheme to improve the accuracy of numerical precipitation forecast.

In summary, the general idea of the method provided by the present invention is to forecast historical precipitation by various parametric scheme combinations to forecast historical precipitation, analyze the parameterization scheme combination with the best performance in each precipitation forecast, and record the surface pressure distribution situation at the beginning of the forecast and the optimal parameterization scheme combination. When the future forecast is carried out, the forecast which is closest to the current surface pressure distribution situation is found from the historical database, and the corresponding optimal parameterization scheme combination is used to carry out the forecast. The forecast comprises three parts: forecast period, database construction of surface pressure distribution situation and optimal parameterization scheme combination, and numerical precipitation forecast.

(I) Setting the forecast period: setting the forecast period of numerical precipitation forecast according to forecast demands, wherein the forecast period is generally in a range of 1 to 7 days, including one and seven days.

(II) Database construction of surface pressure distribution situation and optimal parameterization scheme combination, that is, the step of (S1) specifically comprises:
(S11) determining a start time and an end time of the forecast period, which specifically comprises determining the start time Tₛₜₐᵣₜ and the end time T_{end} according to available data;
(S12) determining a parameterization scheme combination sample set, wherein the parameterization scheme combination sample set comprises microphysical parameterization scheme and cumulus convection parameterization scheme with great influence on precipitation forecast, which are generally set as shown in Table 1:

TABLE 1

| Serial | Microphysical | Cumulus convection |
|---|---|---|
| number | parameterization scheme | parameterization scheme |
| 1 | Kessler | Kain-Fritsch |
| 2 | Lin | Kain-Fritsch |
| 3 | WSM6 | Kain-Fritsch |
| 4 | Thompson | Kain-Fritsch |
| 5 | Morrison | Kain-Fritsch |
| 6 | Kessler | Betts-Miller-JanJic |
| 7 | Lin | Betts-Miller-JanJic |
| 8 | WSM6 | Betts-Miller-JanJic |
| 9 | Thompson | Betts-Miller-JanJic |
| 10 | Morrison | Betts-Miller-JanJic |
| 11 | Kessler | Grell3 |
| 12 | Lin | Grell3 |
| 13 | WSM6 | Grell3 |
| 14 | Thompson | Grell3 |
| 15 | Morrison | Grell3; |

(S13) determining a WRF operation scheme, which comprises on based on the start time, the end time and the parameterization scheme combination sample set, developing the WRF operation scheme according to the forecast period, wherein generally, an operation mode of running the number of days in the forecast period forward day by day is adopted, for example, the start time is Jul. 1, 2014, the end time is Oct. 31, 2014, the forecast period is 7 days, the operation mode is able to be set as shown in Table 2:

TABLE 2

| Serial | | | Microphysical | Cumulus convection |
|---|---|---|---|---|
| num- | | | parameteriza- | parameteriza- |
| ber | Start time | End time | tion scheme | tion scheme |
| 1 | 2014-7-1 | 2014-7-8 | Kessler | Kain-Fritsch |
| 2 | 8:00 | 8:00 | Lin | Kain-Fritsch |
| 3 | | | WSM6 | Kain-Fritsch |
| 4 | | | Thompson | Kain-Fritsch |
| 5 | | | Morrison | Kain-Fritsch |
| 6 | | | Kessler | Betts-Miller-JanJic |
| 7 | | | Lin | Betts-Miller-JanJic |
| 8 | | | WSM6 | Betts-Miller-JanJic |
| 9 | | | Thompson | Betts-Miller-JanJic |
| 10 | | | Morrison | Betts-Miller-JanJic |
| 11 | | | Kessler | Grell3 |
| 12 | | | Lin | Grell3 |
| 13 | | | WSM6 | Grell3 |
| 14 | | | Thompson | Grell3 |
| 15 | | | Morrison | Grell3 |
| 16 | 2014-7-2 | 2014-7-9 | Kessler | Kain-Fritsch |
| 17 | 8:00 | 8:00 | Lin | Kain-Fritsch |
| 18 | | | WSM6 | Kain-Fritsch |
| 19 | | | Thompson | Kain-Fritsch |
| 20 | | | Morrison | Kain-Fritsch |
| 21 | | | Kessler | Betts-Miller-JanJic |
| 22 | | | Lin | Betts-Miller-JanJic |
| 23 | | | WSM6 | Betts-Miller-JanJic |
| 24 | | | Thompson | Betts-Miller-JanJic |
| 25 | | | Morrison | Betts-Miller-JanJic |
| 26 | | | Kessler | Grell3 |
| 27 | | | Lin | Grell3 |
| 28 | | | WSM6 | Grell3 |
| 29 | | | Thompson | Grell3 |
| 30 | | | Morrison | Grel13 |
| . . . | . . . | . . . | . . . | . . . ; |

(S14) running the WRF by using the parameterization scheme combination, which specifically comprises according to the determined WRF operation scheme in the step of (S13), running the WRF by using the parameterization scheme combination according to serial number;
(S15) obtaining surface pressure distribution data at the beginning of each WRF operation and a parameterization scheme combination with the minimum forecast error of the each WRF operation, which specifically comprises obtaining the surface pressure distribution data at the beginning of the each WRF operation, calculating an precipitation forecast error of the each parameterization scheme combination of the each WRF operation, selecting the parameterization scheme combination with the minimum forecast error of the each WRF operation as an optimal parameterization scheme combination of the each WRF operation, and building a corresponding relation between the optimal parameterization scheme combination and the surface pressure distribution data at the beginning of the each WRF operation, wherein:
obtaining the surface pressure distribution data at the beginning of the each WRF operation comprises analyzing FNL (final operational global analysis) data, and storing the surface pressure distribution data of a research area in a corresponding historical surface pressure distribution matrix file in the form of rows and columns, so as to form the historical surface pressure distribution situation, wherein a spatial resolution of the FNL is 100 km×100 km, the FNL are common meteorological data in the form of standard Grib2 with many analytical methods;
calculating the precipitation forecast error of the each parameterization scheme combination of the each WRF operation by a formula of

$$Δ P = \vert {\sum }_{d = 1}^{λ} {Pre}_{d} - {\sum }_{d = 1}^{λ} {Obs}_{d} \vert ,$$

wherein ΔP is the precipitation forecast error of the each parameterization scheme combination, λ is the forecast period, Pre_{d} is the precipitation forecast of the d^{th} day, Obs_{d} is an observed precipitation value of the d^{th} day; and
(S16) obtaining the surface pressure distribution data at the beginning of all WRF operations and the parameterization scheme combinations with the minimum forecast error of the all WRF operations by repeating the steps of (S14) and (S15) and storing, so as to obtain the database having the corresponding relation between the historical surface pressure distribution situation and the optimal parameterization scheme combination.

(III) Numerical precipitation forecast, which comprises on the basis of constructing the database having the corresponding relation between the historical surface pressure distribution situation and the optimal parameterization scheme combination, comparing the surface pressure distribution situation at the beginning of each forecast with the historical surface pressure distribution situation recorded in the database before the each forecast, finding the closest sample and the corresponding optimal parameterization scheme combination, taking the optimal parameterization scheme combination as the WRF parameterization scheme combination, that is, the step of (S2) specifically comprises:
(S21) obtaining a surface pressure distribution situation at the beginning of an actual precipitation forecast, and obtaining surface pressure distribution data at the beginning of forecast by analyzing the FNL, and storing the surface pressure distribution data of the research area in a text file in the form of rows and columns, wherein the spatial resolution of the FNL is 100 km×100 km, the FNL are common meteorological data in the form of standard Grib2 with many analytical methods; obtaining the surface pressure distribution situation at the beginning of the actual precipitation forecast by analyzing the FNL, and storing the surface pressure distribution data of the research area in an actual precipitation forecast surface pressure distribution matrix file in the form of rows and columns;
(S22) querying a historical surface pressure distribution situation which is closest to the surface pressure distribution situation at the beginning of the actual precipitation forecast in the database, wherein an optimal parameterization scheme combination corresponding to the historical surface pressure distribution situation is the optimal parameterization scheme combination of the actual precipitation forecast, which specifically comprises:
calculating a degree of deviation between the surface pressure distribution situation at the beginning of the actual precipitation forecast and each historical surface pressure distribution situation in the database, finding a historical surface pressure distribution situation with a smallest degree of deviation by traversing all historical surface pressure distribution situations in the database, wherein the historical surface pressure distribution situation with the smallest degree of deviation is the historical surface pressure distribution situation which is closest to the surface pressure distribution situation at the beginning of the actual precipitation forecast, the optimal parameterization scheme combination corresponding to the historical surface pressure distribution situation with the smallest degree of deviation is the optimal parameterization scheme combination of the actual precipitation forecast, the degree of deviation is calculated by a formula of

$${ε}^{h} = {\sum }_{i = 1}^{m} {\sum }_{j = 1}^{n} \vert {P}_{i , j} - {P}_{i , j}^{h} \vert ,$$

here, ε^{h} is a degree of deviation between the surface pressure distribution situation at the beginning of the actual precipitation forecast and the h^{th} historical surface pressure distribution situation, i is row number, j is column number, m is the largest row number, n is the largest column number, P_{i,j} is the pressure value of the i^{th} row, j^{th} column in the actual precipitation forecast surface pressure distribution matrix file, P_{i,j}^{h} is the pressure value of the i^{th} row, j^{th} column in the historical surface pressure distribution matrix file; and
(S23) carrying out the actual precipitation forecast by running the WRF with the optimal parameterization scheme combination of the actual precipitation forecast.

### Second Embodiment

According to the second preferred embodiment of the present invention, Hanjiang River basin above Danjiangkou Reservoir in China is selected as the research object, and the implementation process of this method is explained in detail as follows.

(I) Setting a forecast period to one day.

(II) Constructing a database having a corresponding relation between a surface pressure distribution situation and an optimal parameterization scheme combination, which specifically comprises:
(S11) setting a start time Tₛₜₐᵣₜ and an end time T_{end} to be 2001-1-1 8:00 and 2010-12-31 8:00 respectively for a total of 10 years;
(S12) determining a parameterization scheme combination sample set, wherein the parameterization scheme combination sample set comprises microphysical parameterization scheme and cumulus convection parameterization scheme with great influence on precipitation forecast, which are generally set as shown in Table 1;
(S13) determining a WRF operation scheme, which comprises on a basis of determination of the start time, the end time, the forecast period and the parameterization scheme combination sample set, developing the WRF operation scheme, wherein a day-by-day forward operation mode is adopted, which is shown in Table 3:

TABLE 3

| Serial | | | Microphysical | Cumulus convection |
|---|---|---|---|---|
| num- | | | parameteriza- | parameteriza- |
| ber | Start time | End time | tion scheme | tion scheme |
| 1 | 2001-1-1 | 2001-1-2 | Kessler | Kain-Fritsch |
| 2 | 8:00 | 8:00 | Lin | Kain-Fritsch |
| 3 | | | WSM6 | Kain-Fritsch |
| 4 | | | Thompson | Kain-Fritsch |
| 5 | | | Morrison | Kain-Fritsch |
| 6 | | | Kessler | Betts-Miller-JanJic |
| 7 | | | Lin | Betts-Miller-JanJic |
| 8 | | | WSM6 | Betts-Miller-JanJic |
| 9 | | | Thompson | Betts-Miller-JanJic |
| 10 | | | Morrison | Betts-Miller-JanJic |
| 11 | | | Kessler | Grell3 |
| 12 | | | Lin | Grell3 |
| 13 | | | WSM6 | Grell3 |
| 14 | | | Thompson | Grell3 |
| 15 | | | Morrison | Grell3 |
| 16 | 2014-7-2 | 2014-7-9 | Kessler | Kain-Fritsch |
| 17 | 8:00 | 8:00 | Lin | Kain-Fritsch |
| 18 | | | WSM6 | Kain-Fritsch |
| 19 | | | Thompson | Kain-Fritsch |
| 20 | | | Morrison | Kain-Fritsch |
| 21 | | | Kessler | Betts-Miller-JanJic |
| 22 | | | Lin | Betts-Miller-JanJic |
| 23 | | | WSM6 | Betts-Miller-JanJic |
| 24 | | | Thompson | Betts-Miller-JanJic |
| 25 | | | Morrison | Betts-Miller-JanJic |
| 26 | | | Kessler | Grell3 |
| 27 | | | Lin | Grell3 |
| 28 | | | WSM6 | Grell3 |
| 29 | | | Thompson | Grell3 |
| 30 | | | Morrison | Grell3 |
| . . . | . . . | . . . | . . . | . . . |
| . . . | 2010-12-30 | 2010-12-31 | Kessler | Kain-Fritsch |
| . . . | 8:00 | 8:00 | Lin | Kain-Fritsch |
| . . . | | | WSM6 | Kain-Fritsch |
| . . . | | | Thompson | Kain-Fritsch |
| . . . | | | Morrison | Kain-Fritsch |
| . . . | | | Kessler | Betts-Miller-JanJic |
| . . . | | | Lin | Betts-Miller-JanJic |
| . . . | | | WSM6 | Betts-Miller-JanJic |
| . . . | | | Thompson | Betts-Miller-JanJic |
| . . . | | | Morrison | Betts-Miller-JanJic |
| . . . | | | Kessler | Grell3 |
| . . . | | | Lin | Grell3 |
| . . . | | | WSM6 | Grell3 |
| . . . | | | Thompson | Grell3 |
| . . . | | | Morrison | Grell3; |

(S14) running the WRF by using the parameterization scheme combination, which specifically comprises according to the determined WRF operation scheme in the step of (S13), running the WRF according to serial number;
(S15) obtaining the surface pressure distribution situation and the optimal parameterization scheme combination of the each WRF operation, which specifically comprises:
firstly obtaining surface pressure distribution data at a beginning of the each WRF operation, which comprises analyzing FNL, and storing surface pressure distribution data of a research area in a text file in a form of rows and columns;
secondly calculating a precipitation forecast error of each parameterization scheme combination of the each WRF operation by a formula of

$$Δ P = \vert {\sum }_{d = 1}^{λ} {Pre}_{d} - {\sum }_{d = 1}^{λ} {Obs}_{d} \vert ,$$

wherein ΔP is the precipitation forecast error of the each parameterization scheme combination, λ is the forecast period, Pre_{d} is the precipitation forecast of the d^{th} day, Obs_{d} is an observed precipitation value of the d^{th} day; and
then selecting the parameterization scheme combination with the minimum ΔP as the optimal parameterization scheme combination of the each WRF operation, so as to form a corresponding relation between the optimal parameterization scheme combination and the surface pressure distribution situation; and
(S16) obtaining the surface pressure distribution data at the beginning of the each WRF operation and the parameterization scheme combination with the minimum forecast error of the each WRF operation by repeating the steps of (S14) and (S15) and storing, so as to obtain the database which is shown in Table 4:

TABLE 4

| | | | Optimal |
|---|---|---|---|
| Serial | | Surface pressure | parameterization |
| number | Time | distribution matrix file | scheme combination |
| 1 | 2001-1-1 | D:\matrix\200101010800.asc | WSM6 + Betts- |
| | 8:00 | | Miller-JanJic |
| 2 | 2001-1-2 | D:\matrix\200101020800.asc | WSM6 + Betts- |
| | 8:00 | | Miller-JanJic |
| 3 | 2001-1-3 | D:\matrix\200101030800.asc | WSM6 + Betts- |
| | 8:00 | | Miller-JanJic |
| 4 | 2001-1-4 | D:\matrix\200101040800.asc | WSM6 + Grell3 |
| | 8:00 | | |
| . . . | . . . | . . . | . . . , |

wherein the column of the surface pressure distribution matrix file shows a path of the file, an internal format of the file is shown as below:

| | | | |
|---|---|---|---|
| 1010 | 1000 | 1003 | 1004 |
| 1000 | 1001 | 1001 | 1001 |
| 1002 | 1003 | 1000 | 1000 |
| 1000 | 1000 | 1000 | 1000, |

here, numbers of the surface pressure distribution matrix file represent pressure values at different spatial positions, a unit of the pressure values is hPa, coordinates of an upper left corner are corresponding to a northwest corner of the spatial position, and coordinates of a lower right corner are corresponding to a southeast corner of the spatial position.

(III) Numerical precipitation forecast, which comprises on a basis of constructing the database having the corresponding relation between the surface pressure distribution situation and the optimal parameterization scheme combination, comparing the surface pressure distribution situation at the beginning of each forecast with the historical surface pressure distribution situation recorded in the database before the each forecast, finding the closest sample and the corresponding optimal parameterization scheme combination, and taking the optimal parameterization scheme combination as the WRF parameterization scheme combination.
(S21) According to the second preferred embodiment, a time period of forecast is from 2014-9-10 to 2014-9-16 for a total of 7 days, a type of forecast is daily rainfall forecast on watershed surface, namely, daily surface cumulative rainfall in Hanjiang River Basin above Danjiangkou with a unit of mm is forecast, the WRF operation is carried out for 7 times, the start time of the WRF operation is at 8 a.m. every morning, the end time of the WRF operation is at 8 a.m. the next morning, daily rainfall statistics is from 8 a.m. every day to 8 a.m. the next day, area rainfall and daily rainfall are professional common terms, the area rainfall is calculated by arithmetic mean method in the second preferred embodiment, an actual measured rainfall from 2014-9-10 to 2014-9-16 is shown in Table 5:

TABLE 5

| Date | Daily rainfall (mm) |
|---|---|
| 2014 Sep. 10 | 24.77 |
| 2014 Sep. 11 | 12.00 |
| 2014 Sep. 12 | 14.38 |
| 2014 Sep. 13 | 20.93 |
| 2014 Sep. 14 | 18.16 |
| 2014 Sep. 15 | 19.39 |
| 2014 Sep. 16 | 11.36 |

(S22) According the method disclosed in the Summary of the present invention, finding the optimal parameterization scheme combination of 8 a.m. every morning which is shown in Table 6:

TABLE 6

| | | Microphysical | Cumulus convection |
|---|---|---|---|
| Serial | | parameterization | parameterization |
| number | Time | scheme | scheme |
| 1 | 2014-9-10 8:00 | WSM6 | Grell3 |
| 2 | 2014-9-11 8:00 | WSM6 | Grell3 |
| 3 | 2014-9-12 8:00 | WSM6 | Grell3 |
| 4 | 2014-9-13 8:00 | WSM6 | Betts-Miller-JanJic |
| 5 | 2014-9-14 8:00 | Morrison | Grell3 |
| 6 | 2014-9-15 8:00 | Morrison | Grell3 |
| 7 | 2014-9-16 8:00 | WSM6 | Grell3 |

(S23) Based on the above parameters, in an order of serial number, carrying out the WRF operation for 7 times, wherein the forecast period of each forecast is 1 day, results are shown in Table 7:

TABLE 7

| Serial | | Forecast | Observed |
|---|---|---|---|
| number | Time | value (mm) | value (mm) |
| 1 | 2014-9-10 8:00 | 22.69 | 24.77 |
| 2 | 2014-9-11 8:00 | 13.12 | 12.00 |
| 3 | 2014-9-12 8:00 | 14.01 | 14.38 |
| 4 | 2014-9-13 8:00 | 18.15 | 20.93 |
| 5 | 2014-9-14 8:00 | 15.99 | 18.16 |
| 6 | 2014-9-15 8:00 | 17.89 | 19.39 |
| 7 | 2014-9-16 8:00 | 14.50 | 11.36 |

It is able to seen that through the method provided by the present invention, the forecast value is very close to the observed value, and the error between the forecast value of 116.35 mm and the observed value of 120.99 mm for 7 days is within 5%, which is able to better forecast the future precipitation.

According to the second preferred embodiment of the present invention, in order to further demonstrate the superiority of this method, a comparative test is set up, fixed parameterization schemes are used to run the WRF to carry out the comparative test. The total rainfall error (absolute value) of 7 days is used as the basis for comparison, and results are shown in Table 8:

TABLE 8

| | Microphysical | Cumulus convection | | |
|---|---|---|---|---|
| Serial | parameterization | parameterization | | Error |
| Number | scheme | scheme | Date | (mm) |
| 1 | Kessler | Kain-Fritsch | 2014 Sep. 9 | 19.29 |
| 2 | Lin | Kain-Fritsch | 2014 Sep. 9 | 12.04 |
| 3 | WSM6 | Kain-Fritsch | 2014 Sep. 9 | 8.21 |
| 4 | Thompson | Kain-Fritsch | 2014 Sep. 9 | 10.66 |
| 5 | Morrison | Kain-Fritsch | 2014 Sep. 9 | 9.45 |
| 6 | Kessler | Betts-Miller-JanJic | 2014 Sep. 9 | 17.52 |
| 7 | Lin | Betts-Miller-JanJic | 2014 Sep. 9 | 14.23 |
| 8 | WSM6 | Betts-Miller-JanJic | 2014 Sep. 9 | 6.59 |
| 9 | Thompson | Betts-Miller-JanJic | 2014 Sep. 9 | 6.77 |
| 10 | Morrison | Betts-Miller-JanJic | 2014 Sep. 9 | 10.44 |
| 11 | Kessler | Grell3 | 2014 Sep. 9 | 18.11 |
| 12 | Lin | Grell3 | 2014 Sep. 9 | 13.56 |
| 13 | WSM6 | Grell3 | 2014 Sep. 9 | 6.27 |
| 14 | Thompson | Grell3 | 2014 Sep. 9 | 6.82 |
| 15 | Morrison | Grell3 | 2014 Sep. 9 | 9.89 |

It is able to be seen that if a fixed parameterization scheme combination is adopted, the error between the forecast value and the measured value obtained by the optimal parameterization scheme combination is 6.27 mm, which is higher than 4.64 mm of the present invention. Therefore, the present invention has the effectiveness and superiority compared with the traditional method.

By adopting the technical solutions mentioned above, the method provided by the present invention has beneficial effects as follows.

The present invention provides a method for dynamically changing a WRF parameterization scheme combination based on a surface pressure distribution situation. The method uses the principle of high correlation between the surface pressure distribution situation and the weather situation to build a database of the surface pressure distribution situation and the optimal parameterization scheme combination, and takes the surface pressure distribution situation at the beginning of forecast as the basis for selecting the optimal parameterization scheme combination, which is more scientific than the traditional parameterization scheme combination. The microphysical parameterization scheme and the cumulus convection parameterization scheme are two key parameterization schemes affecting the accuracy of precipitation forecast. The present invention selects a parameterization scheme combination according to the surface pressure distribution situation at the beginning of forecast, which is able to indirectly reflect the applicability of different parameterization scheme combinations to different weather situations, thus the method provided by the present invention has higher prediction accuracy than the traditional method.

The above are only preferred embodiments of the present invention. It should be noted that, for those skilled in the art, a number of improvements and modifications may be made without departing from the principle of the present invention, and these improvements and modifications shall also be included in the protection scope of the present invention.

1. A method for dynamically changing a WRF parameterization scheme combination based on a surface pressure distribution situation, the method comprising steps of:
(S1) constructing a database having a corresponding relation between a historical surface pressure distribution situation and an optimal parameterization scheme combination; and
(S2) obtaining an optimal parameterization scheme combination corresponding to the historical surface pressure distribution situation by querying a historical surface pressure distribution situation closest to an actual precipitation forecast surface pressure distribution situation in the database, and running WRF by the optimal parameterization scheme combination corresponding to the historical surface pressure distribution situation, so as to carry out an actual precipitation forecast, wherein:
before the step of (S1), the method further comprises a step of setting a forecast period of numerical precipitation forecast according to forecast demands;
the step of (S1) specifically comprises:
(S11) determining a start time and an end time of the forecast period;
(S12) determining a parameterization scheme combination sample set;
(S13) determining a WRF operation scheme;
(S14) carrying out the WRF by each parameterization scheme combination;
(S15) obtaining surface pressure distribution data at a beginning of each WRF operation and a parameterization scheme combination with a minimum forecast error of the each WRF operation; and
(S16) obtaining surface pressure distribution data at the beginning of all WRF operations and all parameterization scheme combinations with the minimum forecast error of the all WRF operations by repeating the steps of (S14) and (S15) and storing, so as to obtain the database having the corresponding relation between the historical surface pressure distribution situation and the optimal parameterization scheme combination.

2. The method for dynamically changing the WRF parameterization scheme combination based on the surface pressure distribution situation according to claim 1, wherein the parameterization scheme combination sample set comprises microphysical parameterization schemes and cumulus convection parameterization schemes.

3. The method for dynamically changing the WRF parameterization scheme combination based on the surface pressure distribution situation according to claim 2, wherein the step of (S13) specifically comprises on a basis of determining the start time, the end time and the parameterization scheme combination sample set, determining the WRF parameterization scheme in combination with the forecast period.

4. The method for dynamically changing the WRF parameterization scheme combination based on the surface pressure distribution situation according to claim 3, wherein the step of (S15) specifically comprises obtaining the surface pressure distribution data at the beginning of the each WRF operation, calculating an precipitation forecast error of the each parameterization scheme combination of the each WRF operation, selecting the parameterization scheme combination with the minimum forecast error of the each WRF operation as an optimal parameterization scheme combination of the each WRF operation, and building a corresponding relation between the optimal parameterization scheme combination and the surface pressure distribution data at the beginning of the each WRF operation.

5. The method for dynamically changing the WRF parameterization scheme combination based on the surface pressure distribution situation according to claim 4, wherein the precipitation forecast error of the each parameterization scheme combination is calculated by a formula of
$$Δ P = \vert {\sum }_{d = 1}^{λ} {Pre}_{d} - {\sum }_{d = 1}^{λ} {Obs}_{d} \vert ,$$
wherein ΔP is the precipitation forecast error of the each parameterization scheme combination, λ is the forecast period, Pre_{d} is a precipitation forecast of the d^{th} day, Obs_{d} is an observed precipitation value of the d^{th} day.

6. The method for dynamically changing the WRF parameterization scheme combination based on the surface pressure distribution situation according to claim 5, wherein the step of (S2) specifically comprises:
(S21) obtaining a surface pressure distribution situation at a beginning of the actual precipitation forecast;
(S22) querying a historical surface pressure distribution situation which is most closest to the surface pressure distribution situation at the beginning of the actual precipitation forecast in the database, wherein an optimal parameterization scheme combination corresponding to the historical surface pressure distribution situation is an optimal parameterization scheme combination of the actual precipitation forecast; and
(S23) carrying out the actual precipitation forecast by carrying out the WRF operation with the optimal parameterization scheme combination of the actual precipitation forecast.

7. The method for dynamically changing the WRF parameterization scheme combination based on the surface pressure distribution situation according to claim 6, wherein the database comprises multiple historical surface pressure distribution situations; each of the multiple historical surface pressure distribution situations is obtained by analyzing FNL (final operational global analysis) data in the WFP mode, and storing surface pressure distribution data of a research area in a corresponding historical surface pressure distribution matrix file in a form of rows and columns, so as to form the historical surface pressure distribution situation; the surface pressure distribution situation at the beginning of the actual precipitation forecast is obtained by analyzing the FNL data, and storing the surface pressure distribution data of the research area in an actual precipitation forecast surface pressure distribution matrix file in the form of rows and columns, so as to form the surface pressure distribution situation at the beginning of the actual precipitation forecast.

8. The method for dynamically changing the WRF parameterization scheme combination based on the surface pressure distribution situation according to claim 7, wherein the step of (S22) specifically comprises calculating a degree of deviation between the surface pressure distribution situation at the beginning of the actual precipitation forecast and each historical surface pressure distribution situation in the database, finding a historical surface pressure distribution situation with a smallest degree of deviation by traversing all historical surface pressure distribution situations in the database, wherein the historical surface pressure distribution situation with the smallest degree of deviation is the historical surface pressure distribution situation which is most closest to the surface pressure distribution situation at the beginning of the actual precipitation forecast, the optimal parameterization scheme combination corresponding to the historical surface pressure distribution situation with the smallest degree of deviation is the optimal parameterization scheme combination of the actual precipitation forecast, the degree of deviation is calculated by a formula of
$${ε}^{h} = {\sum }_{i = 1}^{m} {\sum }_{j = 1}^{n} \vert {P}_{i , j} - {P}_{i , j}^{h} \vert ,$$
here ε^{h} is a degree of deviation between the surface pressure distribution situation at the beginning of the actual precipitation forecast and a h^{th} historical surface pressure distribution situation, i is row number, j is column number, m is a largest row number, n is a largest column number, P_{i,j} is a pressure value of i^{th} row, j^{th} column in the actual precipitation forecast surface pressure distribution matrix file, P_{i,j}^{h} is a pressure value of the i^{th} row, j^{th} column in the historical surface pressure distribution matrix file.
